(19) United States
(12) Patent Application Publication
(10) Pub. No.: US 2012/0113063 A1
(43) Pub. Date: May 10, 2012

(54) TOUCH PANEL AND A MANUFACTURING METHOD THE SAME

(75) Inventors: Woon Chun Kim, Suwon (KR); Sang Hwan Oh, Anyang-si (KR); Yong Soo Oh, Seongnam-si (KR); Jong Young Lee, Suwon (KR)

(73) Assignee: SAMSUNG ELECTRO-MECHANICS CO., LTD., Gyunggi-do (KR)

(21) Appl. No.: 13/039,246

(22) Filed: Mar. 2, 2011

(30) Foreign Application Priority Data
Nov. 10, 2010 (KR) 1020100111546

(51) Int. Cl. G06F 3/042; G06F 1/16; G03F 7/20

(52) U.S. Cl. 345/176; 430/315; 29/846

(57) ABSTRACT

Disclosed herein are a touch panel and a method of manufacturing the same. The touch panel 100 according to the present invention includes a transparent substrate 110; a discoloring layer 120 formed on one surface of the transparent substrate 110; and a transparent electrode 130 formed on the discoloring layer 120, wherein the transparent electrode 130 is patterned to have an opening 135 and the discoloring layer 120 selectively discolors only the portion 125 corresponding to the opening 135 into color corresponding to the transparent electrode 130. The present invention uses the discoloring layer 120 discolored into color corresponding to the transparent electrode 130 to prevent the recognition of the patterned transparent electrode 130 by a user, thereby making it possible to the improve visibility of the touch panel 100.

### CROSS REFERENCE TO RELATED APPLICATION

This application claims the benefit of Korean Patent Application No. 10-2010-0111546, filed on Nov. 10, 2010, entitled “Touch Panel and A Manufacturing Method the Same” which is hereby incorporated by reference in its entirety into this application.

### BACKGROUND OF THE INVENTION

1. Technical Field

The present invention relates to a touch panel and a method of manufacturing the same.

2. Description of the Related Art

Alongside the growth of computers using digital technology, devices assisting computers have also been developed, and personal computers, portable transmitters and other personal information processors execute processing of text and graphics using a variety of input devices such as a keyboard and a mouse.

While the rapid advancement of the information-based society has been widening the use of computers more and more, there have been occurring the problems of it being difficult to efficiently operate products using only the keyboard and mouse as being currently responsible for the input device function. Thus, the demand for a device that is simple, has minimum malfunction, and has the capability to easily input information is increasing.

Furthermore, current techniques for input devices exceed the level of fulfilling general functions and thus are progressing towards techniques related to high reliability, durability, innovation, designing and manufacturing. To this end, a touch panel has been developed as an input device capable of inputting information such as text and graphics.

The touch panel is mounted on the display surface of an image display device such as an electronic organizer, a flat panel display including a liquid crystal display (LCD), a plasma display panel (PDP), an electroluminescence (El) element or the like, or a cathode ray tube (CRT), so that a user selects the information desired while viewing the image display device.

The touch panel is classifiable as a resistive type, a capacitive type, an electromagnetic type, a surface acoustic wave (SAW) type, and an infrared type. The type of touch panel selected is one that is adapted for an electronic product in consideration of not only signal amplification problems, resolution differences and the degree of difficulty of designing and manufacturing technology but also in light of optical properties, electrical properties, mechanical properties, resistance to the environment, input properties, durability and economic benefits of the touch panel. Currently, a capacitive touch panel and a digital resistive touch panel, which can implement a multi-touch, have been prevalently used in a broad range of fields.

However, in the capacitive touch panel and the digital resistive touch panel according to the prior art, the shape of the patterned transparent electrode is recognized by the user. For example, when the transparent electrode is patterned in a bar type, the user recognizes the bar shape and when the transparent electrode is patterned in a diamond type, the user recognizes the diamond shape. Therefore, the touch panel according to the prior art has problems in that the images output from the image display device are deteriorated due to the patterned transparent electrode and the visibility is deteriorated.

### SUMMARY OF THE INVENTION

The present invention has been made in effort to provide a touch panel capable of preventing the recognition of the patterned transparent electrodes by a user by adopting discoloring layers discolored into colors corresponding to the transparent electrodes, and a method of manufacturing the same.

According to a preferred embodiment of the present invention, there is provided a touch panel, including: a transparent substrate; a discoloring layer formed on one surface of the transparent substrate; and a transparent electrode formed on the discoloring layer, wherein the transparent electrode is patterned to have an opening and the discoloring layer selectively discolors only the portion corresponding to the opening into color corresponding to the transparent electrode.

The discoloring layer may be made of a polymeric material containing latent acid and color former.

The transparent electrode may be made of a conductive polymer including poly-3,4-ethylenedioxythiophene/polystyrenesulfonate (PEDOT/PSS), polyaniline, polyacetylene, or polyphenylenevinylene.

According to another preferred embodiment of the present invention, there is provided a touch panel, including: a transparent substrate: a transparent electrode formed on one surface of the transparent substrate; and a discoloring layer formed on the other surface of the transparent substrate, wherein the transparent electrode is patterned to have an opening and the discoloring layer selectively discolors only the portion corresponding to the opening into color corresponding to the transparent electrode.

The discoloring layer may be made of a polymeric material containing latent acid and color former.

The transparent electrode may be made of a conductive polymer including poly-3,4-ethylenedioxythiophene/polystyrenesulfonate (PEDOT/PSS), polyaniline, polyacetylene, or polyphenylenevinylene.

According to a first preferred embodiment of the present invention, there is provided a method of manufacturing a touch panel, including: (A) sequentially forming a discoloring layer and a transparent electrode on one surface of a transparent substrate; and (B) patterning the transparent electrode to form the opening and selectively discoloring only a portion corresponding to the opening in the discoloring layer into color corresponding to the transparent electrode.

Step (B) may include: (B1) arranging a patterned peelable mask on the transparent electrode; (B2) patterning the transparent electrode to form the opening by selectively removing the exposed transparent electrode from the patterned peelable mask by an etching process; and (B3) discoloring only the portion corresponding to the opening in the discoloring layer into color corresponding to the transparent electrode by selectively irradiating laser or light thereto.

At step (B), only the portion corresponding to the opening in the discoloring layer into color corresponding to the transparent electrode may be selectively discolored by the laser, while patterning the transparent electrode to form the opening by irradiating the laser thereto.

At step (A), the transparent electrode may be made of a conductive polymer including poly-3,4-ethylenedioxythiophene/polystyrenesulfonate (PEDOT/PSS), polyaniline, polyacetylene, or polyphenylenevinylene.

The laser may be UV laser and the light may be UV light.

The laser may be UV laser.

At step (A), the discoloring layer may be made of a polymeric material containing latent acid and color former.

According to a second preferred embodiment of the present invention, there is provided a method of manufacturing a touch panel, including: (A) forming a transparent electrode on one surface of a transparent substrate and forming a discoloring layer on the other surface of the transparent substrate; and (B) patterning the transparent electrode to form an opening and selectively discoloring only a portion corresponding to the opening in the discoloring layer into color corresponding to the transparent electrode.

Step (B) may include: (B1) arranging a patterned peelable mask on the transparent electrode; (B2) patterning the transparent electrode to form the opening by selectively removing the exposed transparent electrode from the patterned peelable mask by an etching process; and (B3) discoloring only the portion corresponding to the opening in the discoloring layer into color corresponding to the transparent electrode by selectively irradiating laser or light thereto.

At step (B), only the portion corresponding to the opening in the discoloring layer into color corresponding to the transparent electrode may be selectively discolored by the laser, while patterning the transparent electrode to form the opening by irradiating the laser thereto.

At step (A), the transparent electrode may be made of a conductive polymer including poly-3,4-ethylenedioxythiophene/polystyrenesulfonate (PEDOT/PSS), polyaniline, polyacetylene, or polyphenylenevinylene.

The laser may be UV laser and the light may be UV light.

The laser may be UV laser.

At step (A), the discoloring layer may be made of a polymeric material containing latent acid and color former.

### BRIEF DESCRIPTION OF THE DRAWINGS

FIG. 1 is a cross-sectional view of a touch panel according to a first preferred embodiment of the present invention;

FIG. 2 is a cross-sectional view of a touch panel according to a second preferred embodiment of the present invention;

FIGS. 3 to 7 are cross-sectional views showing a method of manufacturing a touch panel according to the first preferred embodiment of the present invention in a process sequence;

FIGS. 8 to 10 are cross-sectional views showing a method of manufacturing a touch panel according to the modified example of the first preferred embodiment of the present invention in a process sequence;

FIGS. 11 to 13 are cross-sectional views of a touch panel manufactured using the first preferred embodiment of the present invention;

FIGS. 14 to 18 are cross-sectional views showing a method of manufacturing a touch panel according to the second preferred embodiment of the present invention in a process sequence;

FIGS. 19 to 21 are cross-sectional views showing a method of manufacturing a touch panel according to the modified example of the second preferred embodiment of the present invention in a process sequence; and

FIGS. 22 to 23 are cross-sectional views of a touch panel manufactured using the second preferred embodiment of the present invention.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted.

Hereinafter, preferred embodiments of the present invention will be described in detail with reference to the accompanying drawings.

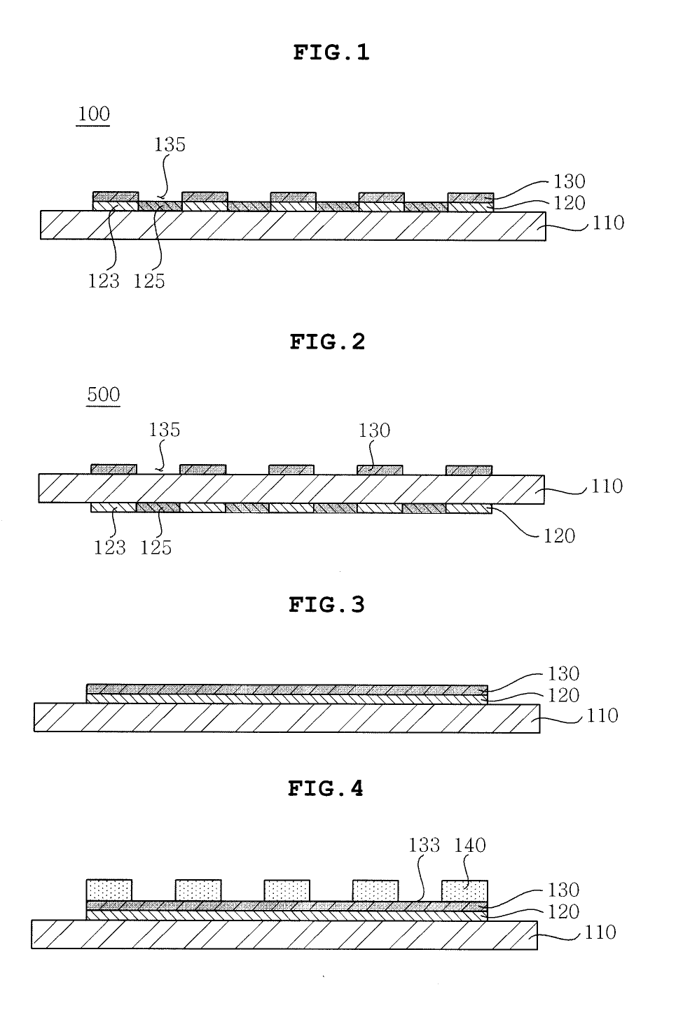

FIG. 1 is a cross-sectional view of a touch panel according to a first preferred embodiment of the present invention.

As shown in FIG. 1, a touch panel 100 according to the present embodiment is configured to include a transparent substrate 110, a discoloring layer 120 formed on one surface of the transparent substrate 110, and a transparent electrode 130 formed on a discoloring layer 120, wherein the transparent electrode 130 is patterned to have an opening 135 and only the portion 125 corresponding to the opening 135 in the discoloring layer 120 is selectively discolored into a color corresponding to the transparent electrode 130.

The transparent substrate 110 serves to provide a region in which the discoloring layer 120 and the transparent electrode 130 will be formed. In this case, the transparent substrate 110 should be provided with a supporting force capable of supporting the discoloring layer 120 and the transparent electrode 130 and transparency through which a user can recognize an image provided from an image display apparatus. Considering the supporting force and transparency, the material of the transparent substrate 110 and may include polyethyleneterephthalate (PET), polycarbonate (PC), polymethylmethacrylate (PMMA), polyethylenenaphthalate (PEN), polyethersulfone (PES), cyclic olefin copolymer (COC), triacetylcellulose (TAC) film, polyvinyl alcohol (PVA) film, polyimide (PI) film, polystyrene (PS), biaxially oriented polystyrene (BOPS; containing K resin), glass or reinforced glass, and so on, but is not particularly limited thereto. Meanwhile, it is preferable to perform a high-frequency treatment or a primer treatment in order to activate one surface of the transparent substrate 110. An adhesion between the transparent substrate 110 and the discoloring layer 120 can be improved by activating one surface of the transparent substrate 110.

The transparent electrode 130 serves to generate signals when a user touches the panel to allow a controller to recognize touched coordinates and is formed in the discoloring layer 120. In this case, the transparent electrode 130 may be formed using a generally used indium tin oxide (ITO) as well as the conductive polymer including poly-3,4-ethylenedioxythiophene/polystyrenesulfonate (PEDOT/PSS), polyaniline, polyacetylene, polyphenylenevinylene, or the like. Among others, when the transparent electrode 130 is made of the PEDOT/PSS, it is advantageous in improving flexibility, simplifying a coating process, or the like. However, the transparent electrode 130 appears blue, such that it is difficult to practically use the method of using the PEDOT/PSS due to chrominance caused between the transparent electrode 130 and the opening 135 when the transparent electrode 130 is patterned. However, the touch panel 100 according to the present embodiment adopts the discoloring layer 120 to discolor only the portion 125 corresponding to the opening 135 between the transparent electrodes 130 into blue corresponding to the transparent electrode 130 in order to remove the chrominance between the transparent electrode 130 and the opening 135, thereby making it possible to prevent the recognition of the transparent electrode 130 by the user even though the transparent electrode 130 is made of the PEDOT/PSS. The method of removing the chrominance between the transparent electrode 130 and the opening 135 by selectively discoloring the discoloring layer 120 will be described in detail.

Meanwhile, the transparent electrode 130 may be formed on the discoloring layer 120 by a dry process, such as sputtering, evaporation, or the like, dip coating, spin coating, roll coating, spray coating, etc. Thereafter, the transparent electrode 130 may be patterned by being etched by an etching process or removed by laser.

The discoloring layer 120 serves to improve the visibility of the touch panel 100 by preventing the recognition of the patterned transparent electrode 130 by the user and is formed on one surface of the transparent substrate 110. In this case, only the portion 125 corresponding to the opening 135 between the patterned transparent electrode 130 in the discoloring layer 120 is discolored into the transparent electrode 130. Since the portion 125 corresponding to the opening in the discoloring layer 120 is discolored into the same color as the transparent electrode 130, the user cannot recognize the chrominance between the transparent electrode 130 and the opening 135 even though the transparent electrode 130 is patterned to have the opening 135. Meanwhile, the portion 123 corresponding to the transparent electrode 130 in the discoloring layer 120 maintains an original color while being not discolored. It is preferable that the original color is a transparent color not having an effect on the transparency of the transparent substrate 110.

In addition, the discoloring layer 120 may be made of a polymeric material containing latent acid and color former. In this case, when UV laser or UV light is irradiated to the discoloring layer 120 made of the polymeric material, the latent acid is converted into acid by absorbing UV energy and then, reacts with the color former, thereby discoloring the specific portion 125 of the discoloring layer 120. In this case, the latent acid itself is not acid but contains proton and is preferably degraded when the UV laser or the UV light is irradiated. For example, the preferable latent acid is a compound according to Chemical Formula 1.

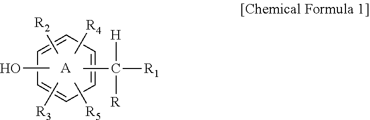

Reviewed in more detail, in Chemical Formula 1, ring A may contain one or more hetero atom or an anelated ring and R₁ is hydrogen, alkyl, alkenyl, or aryl, R₂, R₃, R₄, and R₅, which are independently from each other, are hydrogen or a functional substituent, and R is C₁-C₆ alkyl, —Z₁-Q₁ or —Z₂-Q₂. Herein, Z₁ is a single bonding and S, NH, or O, Q₁ has a ring atom number of 5 to 9 selected from C, S, O, and N, and is a heterocyclic ring system having carbon number of 2 or more in the ring system, Z₂ is C₁-C₄ alkyl capable of being substituted by C₁-C₄ alkyl or Q₃ (Q₃ is C₁-C₄ alkyl or phenyl capable of being substituted by hydroxy 1 to 3 times, C₅-C₈ has atom number of 5 to 9 selected from C₅-C₈ cyclo alkyl and/or C, S, O, and N, and the carbon number in the ring system is a hetero cyclic ring system of 2 or more), Q₂ is phenyl capable of being substituted by C₁-C₄ alkyl or hydroxyl 1 to 3 times, has a ring atom number of 5 to 9 selected from C₅-C₈ cyclo alkyl and/or C, S, O, and N, and is a heterocyclic ring system having carbon number of 2 or more in the ring system, and a hydrogen atom of a carbon atom at α-position of R may be divided by the irradiation of the UV laser or the UV light.

In addition, as described above, when the transparent electrode 130 is made of PEDOT/PSS, the transparent electrode 130 appears blue, such that the discoloring layer 120 should be discolored into blue. Therefore, it is preferable that the discoloring layer 120 is made of a polymeric material containing a latent acid according to Chemical Formula 2 in the latent acid and the color former according to Chemical Formulas 3 to 5 in the color former.

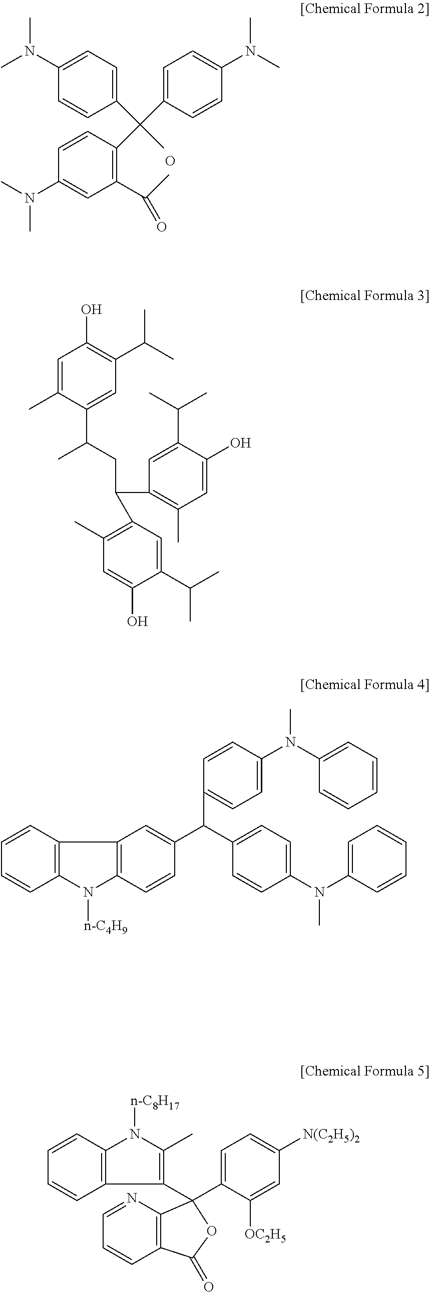

When the discoloring layer 120 is made of the polymeric material containing the latent acid according to Chemical Formula 2 and the color former according to Chemical Formulas 3 to 5 and then, is irradiated with the UV laser or the UV light, it appears blue, thereby making it possible to remove the PEDOT/PSS and the chrominance. Therefore, even though the transparent electrode 130 is made of the PEDOT/PSS, the visibility of the touch panel 100 has not been affected.

However, the polymeric material containing the latent acid and the color former is exemplified and therefore, the present invention is not limited thereto. When color corresponding to the transparent electrode 130 may be implemented, all the materials known in the art may be used.

FIG. 2 is a cross-sectional view of a touch panel according to a second preferred embodiment of the present invention.

As shown in FIG. 2, a touch panel 500 according to the present embodiment is configured to include the transparent substrate 110, the transparent electrode 130 formed on one surface of the transparent substrate 110, and the discoloring layer 120 formed on the other surface of the transparent substrate 110, wherein the transparent electrode 130 is patterned to have the opening 135 and only the portion 125 corresponding to the opening 135 in the discoloring layer 120 is selectively discolored into a color corresponding to the transparent electrode 130.

The greatest difference between the touch panel 100 according to the first embodiment as described above and the touch panel 500 according to the present embodiment is the formation position of the discoloring layer 120. That is, there is a difference in that in the touch panel 100 according to the first preferred embodiment the discoloring layer 120 is formed at the lower side of the transparent electrode 130 and in the touch panel 500 according to the present embodiment the discoloring layer 120 is formed at an opposite surface to the transparent electrode 130 based on the transparent substrate 110. Therefore, the above-mentioned difference will be described and therefore, the repeated contents will be omitted.

The transparent substrate 110 serves to provide an area in which the discoloring layer 120 and the transparent electrode 130 will be formed. The transparent electrode 130 is formed on one surface of the transparent substrate 110 and the discoloring layer 120 is formed on the other surface of the transparent substrate 110. Therefore, it is preferable that a high frequency treatment or a primer treatment is performed on both surfaces of the transparent substrate 110 in order to improve adhesion between the transparent substrate 110 and the transparent electrode 130, between the transparent substrate 110 and the discoloring layer 120.

The transparent electrode 130 serves to generate signals when a user touches the panel to allow the controller to recognize touched coordinates. The transparent electrode 130 is formed on one surface of the transparent substrate 110. In this case, the transparent electrode 130 may be made of indium tin oxide or a conductive polymer, where an example of the conductive polymer may include PEDOT/PSS, polyaniline, polyacetylene, or polyphenylvinylene, or the like. Meanwhile, the transparent electrode 130 is patterned to have the opening 135 and the chrominance is thus generated between the transparent electrode 130 and the opening 135. The touch panel 500 according to the present embodiment selectively discolors the discoloring layer 120 to remove the chrominance between the transparent electrode 130 and the opening 135. The detailed description thereof will be described below.

The discoloring layer 120 cannot prevent the recognition of the patterned transparent electrode 130 by the user to improve the visibility of the touch panel 500 and is formed on the other surface (an opposite surface to a surface on which the transparent electrode 130 is formed) of the transparent substrate 110. In this configuration, only the portion 125 corresponding to the opening 135 in the discoloring layer 120 is discolored into color corresponding to the transparent electrode 130 and the user cannot recognize the chrominance of the transparent electrode 130 and the opening 135, such that the visibility of the touch panel 500 cannot be improved.

Meanwhile, the discoloring layer 120 may be made of a polymeric material containing latent acid and color former, similar to the first preferred embodiment. In particular, when the transparent electrode 130 made of PEDOT/PSS appears blue, the discoloring layer 120 is made of polymeric material containing latent acid of Chemical Formula 2 and color former of Chemical Formulas 3 to 5, such that the discoloring layer 120 may also be discolored into blue.

FIGS. 3 to 7 are cross-sectional views showing a method of manufacturing a touch panel according to the first preferred embodiment of the present invention in a process sequence and FIGS. 8 to 10 are cross-sectional views showing a method of manufacturing a touch panel according to the modified example of the first preferred embodiment of the present invention in a process sequence.

As shown in FIGS. 3 to 7, a method of manufacturing the touch panel 100 according to the present embodiment of the present invention is configured to include (A) forming the discoloring layer 120 on one surface of the transparent substrate 110 and the transparent electrode 130 in sequence; and (B) patterning the transparent electrode 130 to form the opening 135 and discoloring only the portion 125 corresponding to the opening 135 in the discoloring layer 120 into color corresponding to the transparent electrode 130.

First, as shown in FIG. 3, the discoloring layer 120 and the transparent electrode 130 are sequentially formed on one surface of the transparent substrate 110. In this case, the discoloring layer 120 may be made of the polymeric material containing the latent acid of Chemical Formula 2 and the color former of Chemical Formulas 3 to 5, but is not necessarily limited thereto. Further, it is preferable that a high frequency treatment or a primer treatment is performed on one surface of the transparent substrate 110 in order to improve the adhesion between the discoloring layer 120 and the transparent substrate 110. Meanwhile, the transparent electrode 130 is preferably made of PEDOT/PSS having excellent flexibility and making the coating process simple. Further, the transparent electrode 130 may be made of a conductive polymer including indium tin oxide (ITO), polyaniline, polyacetylene, or polyphenylvinylene, or the like. When the transparent electrode 130 is made of PEDOT/PSS, the transparent electrode 130 appears blue.

Next, as shown in FIG. 4, a step of arranging the patterned peelable mask 140 on the transparent electrode 130 is performed. In this case, the peelable mask 140 is used to selectively etch the transparent electrode 130. During the next step, the exposed transparent electrode 133 is removed from the peelable mask 140. Therefore, the peelable mask 140 should be patterned in the same as the pattern of the transparent electrode 130.

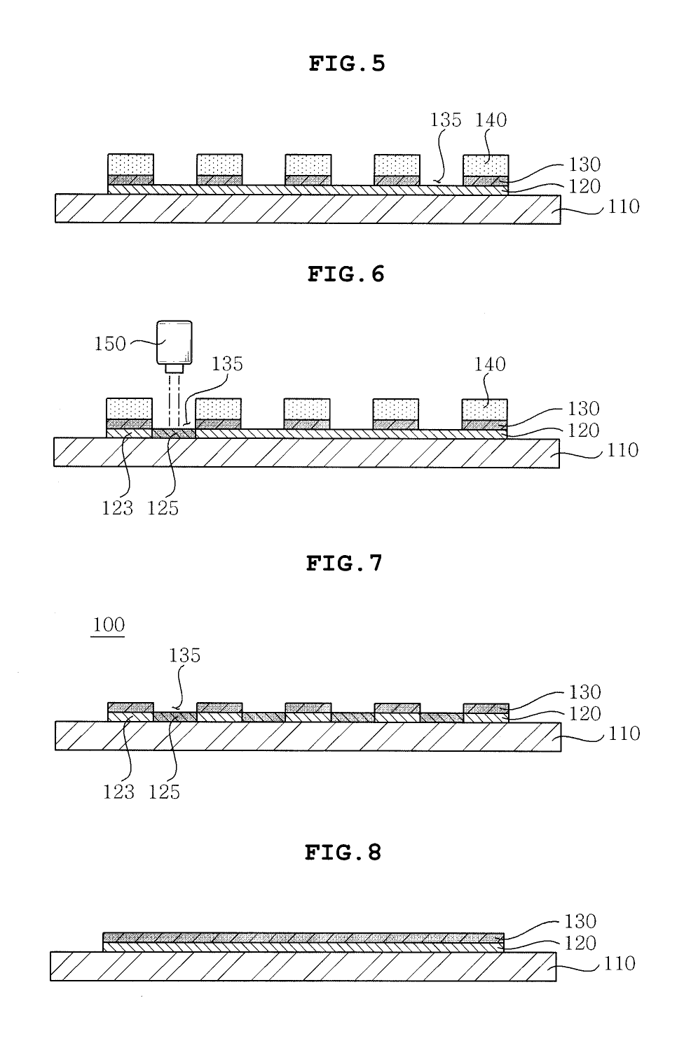

Next, as shown in FIG. 5, a step of patterning is performed to form the opening 135 by selectively removing the transparent electrode 130 using the etching process. After the peelable mask 140 is arranged on the transparent electrode 130, an etchant such as hydrochloric acid, etc., is added to the transparent electrode 130, such that only the transparent electrode 133 exposed from the peelable mask 140 is selectively removed, thereby forming the opening 135.

Next, as shown in FIG. 6, a step of discoloring only the portion 125 corresponding to the opening 135 in the discoloring layer 120 is discolored into color corresponding to the transparent electrode 130 by selectively irradiating laser 150 or light. The discoloring step will be described based on the case where the transparent electrode 130 is made of PEDOT/PSS and the discoloring layer 120 is made of the polymeric material containing the latent acid of Chemical Formula 2 and the color former of Chemical Formulas 3 to 5. Since the transparent electrode 130 is made of PEDOT/PSS, the transparent electrode 130 appears blue, such that the chrominance is generated between the transparent electrode 130 and the opening 135. However, during the discoloring step, the transparent electrode is discolored into blue by irradiating the UV laser 150 or the UV light to the portion 125 corresponding to the opening 135 in the discoloring layer 120. Consequently, the chrominance is removed between the transparent electrode 130 and the opening 135 and therefore, the user cannot recognize the transparent electrode 130, thereby making it possible to improve the visibility. Due to the peelable mask 140, the UV laser 150 or the UV light is irradiated to only the portion 125 corresponding to the opening 135 in the discoloring layer 120 140 and the UV laser 150 or the UV light is shielded in the remaining portion 123. Therefore, it is possible to accurately discolor only the necessary portion 125 in the discoloring layer 120.

Next, as shown in FIG. 7, a step of removing the peelable mask 140 is performed after the discoloring layer 120 is selectively discolored. Since the step of patterning the transparent electrode 130 and the step of discoloring the discoloring layer 120 are completed, the peelable mask 140 is not needed any more and is thus removed during the step of removing the peelable mask. Herein, the peelable mask 140 may be removed without damaging the transparent electrode 130 using tweezers.

Meanwhile, as shown in FIGS. 8 to 10, the method of manufacturing the touch panel 100 according to the present embodiment may omit the etching process using the peelable mask 140 and directly pattern the transparent electrode 130 with a laser 155.

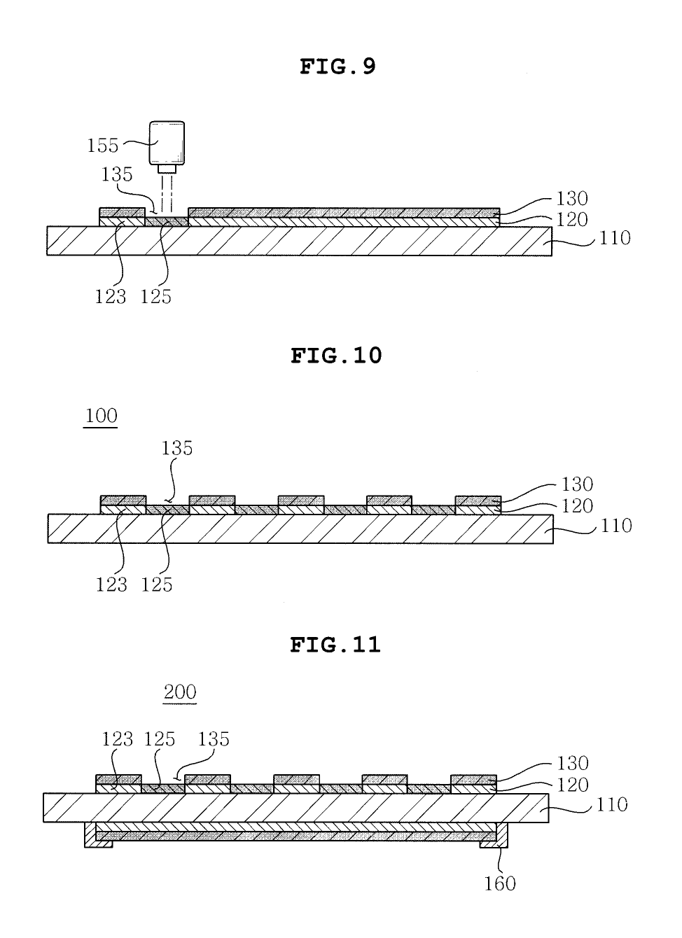

First, as shown in FIG. 8, after the discoloring layer 120 and the transparent electrode 130 are formed on one surface of the transparent substrate 110, as shown in FIGS. 9 and 10, the discoloring layer 120 may be discolored by the laser 155 while patterning the transparent electrode 130 by irradiating the laser 155 thereto. That is, only the portion 125 corresponding to the opening 135 in the discoloring layer 120 is selectively discolored into the same color as the transparent electrode 130 by using the UV laser 155 while patterning the transparent electrode 130 to form the opening 135 by using the UV laser 155. The step of patterning the transparent electrode 130 and the step of discoloring the discoloring layer 120 are performed simultaneously, thereby making it possible to simplify the manufacturing process and shorten the lead time.

In the touch panel 100 according to the present embodiment, the transparent electrode 130 has a single layer structure, such that it may be used as a self capacitive type touch panel or a mutual capacitive type touch panel. Further, various types of touch panels including the structure may be manufactured as described below.

FIGS. 11 to 13 are cross-sectional views of a touch panel manufactured using the first preferred embodiment of the present invention.

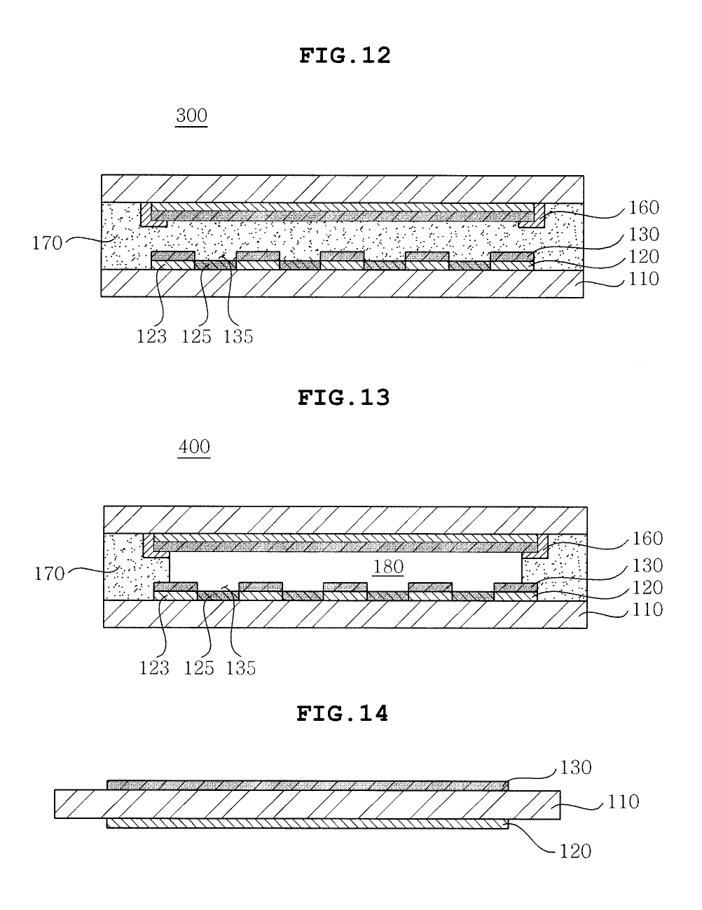

As shown in FIG. 11, a mutual capacitive touch panel 200 (see FIG. 11) may be manufactured so that the transparent electrodes 130 are on both surfaces of a transparent substrate 110 to be vertical to each other. Besides, as shown in FIGS. 12 and 13, the mutual capacitive touch panel 300 (see FIG. 12) or the multi resistive type touch panel 400 (see FIG. 13) may be manufactured by preparing two transparent substrates 110 having the transparent electrode 130 formed on one surface thereof and bonding the two transparent substrates 110 using an adhesive layer 170 so that the transparent electrodes 130 are vertically opposite to each other. Herein, in the case of the mutual capacitive touch panel 300 (see FIG. 12), the adhesive layer 170 is bonded to the entire surface of the transparent substrate 110 so that the two transparent electrodes 130 opposite to each other are insulated. On the other hand, in the case of the multi resistive type touch panel 400 (see FIG. 13), the adhesive layer 170 is attached to only the edge of the transparent substrate 110 and thus, when the pressure of the user is applied to the adhesive layer 170, two transparent electrodes 130 may contact each other through an air-gap 180. Meanwhile, an electrode wiring 160 receiving electrical signals from the transparent electrode 130 is printed at both ends of the transparent electrode 130. In this case, the electrode wirings 160 may be printed by using a screen printing method, a gravure printing method, or an inkjet printing method, or the like. Further, the electrode wiring 160 may be made of silver (Ag) paste or organic Ag having superior electrical conductivity, but the present invention is not limited thereto. In addition, a conductive polymer, carbon black (including CNT), or a low resistive metal including metal or a metal oxide such as ITO may be used. Meanwhile, although the electrode wirings 160 are illustrated to be connected to both ends of the transparent electrode 130 in figures, they may also be connected to only one end of the transparent electrode 130.

FIGS. 14 to 18 are cross-sectional views showing a method of manufacturing a touch panel according to the second preferred embodiment of the present invention in a process sequence and FIGS. 19 and 21 are cross-sectional views showing a method of manufacturing a touch panel according to the modified example of the second preferred embodiment of the present invention in a process sequence.

As shown in FIGS. 14 to 18, a method of manufacturing the touch panel 500 according to the preferred embodiment of the present invention is configured to include (A) forming the transparent electrode 130 on one surface of the transparent substrate 110 and the discoloring layer 120 on the other surface of the transparent substrate 110 and (B) patterning the transparent electrode 130 to form the opening 135 and selectively discoloring only the portion 125 corresponding to the opening 135 in the discoloring layer 120 into color corresponding to the transparent electrode 130.

First, as shown in FIG. 14, a step of forming the transparent electrode 120 on one surface of the transparent substrate 110 and the discoloring layer 120 on the other surface of the transparent substrate 110 is performed. In this case, the discoloring layer 120 may be made of the polymeric material containing the latent acid of Chemical Formula 2 and the color former of Chemical Formulas 3 to 5, but is not necessarily limited thereto. Further, it is preferable that the high frequency treatment or the primer treatment is performed on both surfaces of the transparent substrate 110 in order to improve the adhesion between the discoloring layer 120 and the transparent substrate 110 and between the transparent electrode 130 and the transparent substrate 110. Meanwhile, the transparent electrode 130 may be made of indium tin oxide (ITO) or a conductive polymer, where an example of the conductive polymer may include PEDOT/PSS, polyaniline, polyacetylene, or polyphenylvinylene, or the like. When the transparent electrode 130 is made of PEDOT/PSS, the transparent electrode 130 appears blue.

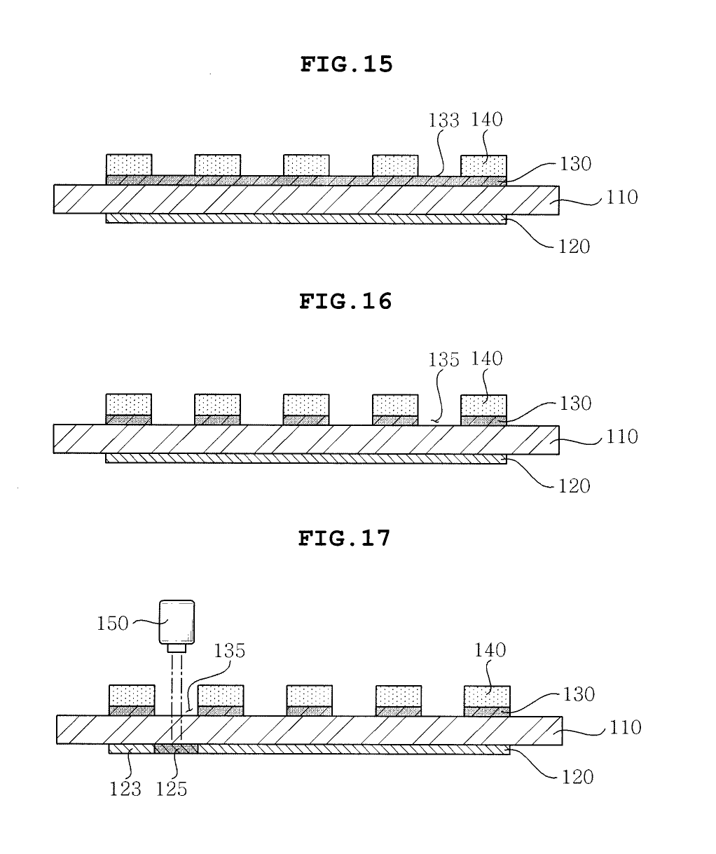

Next, as shown in FIG. 15, a step of arranging the patterned peelable mask 140 on the transparent electrode 130 is performed.

Next, as shown in FIG. 16, a step of patterning is performed to form the opening 135 by selectively removing the transparent electrode 130 using the etching process. After the peelable mask 140 is arranged on the transparent electrode 130, an etchant such as hydrochloric acid, etc., is added to the transparent electrode 130, such that only the transparent electrode 133 (see FIG. 15) exposed from the peelable mask 140 is selectively removed, thereby forming the opening 135. The present embodiment can previously prevent the discoloring layer 120 from being etched together when the transparent electrode 130 is patterned by the etching process, since the discoloring layer 120 is formed on an opposite surface of the transparent electrode 130 based on the transparent substrate 110.

Next, as shown in FIG. 17, a step of discoloring only the portion 125 corresponding to the opening 135 in the discoloring layer 120 is discolored into color corresponding to the transparent electrode 130 by selectively irradiating laser 150 or light. In this case, the discoloring layer 120 may be made of the polymeric material containing the latent acid of Chemical Formula 2 and the color former of Chemical Formulas 3 to 5. In this case, the transparent electrode is discolored into blue by irradiating the UV laser 150 or the UV light to the portion 125 corresponding to the opening 135 in the discoloring layer 120. Therefore, the chrominance may be removed between the transparent electrode 130 and the opening part 135. Meanwhile, the peelable mask 140 is used in the above-mentioned etching process and the discoloring step, thereby making it possible to accurately irradiate the laser 150 or the light to only the portion 125 corresponding to the opening 135 in the discoloring layer 120.

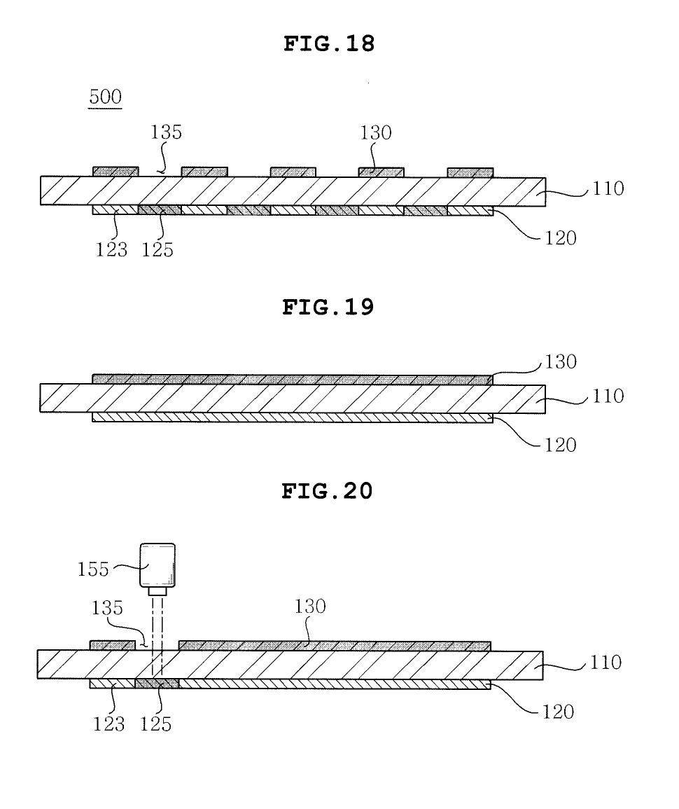

Next, as shown in FIG. 18, a step of removing the peelable mask 140 is performed after the discoloring layer 120 is selectively discolored. Herein, the peelable mask 140 may be peeled and removed without damaging the transparent electrode 130 using tweezers, etc.

Meanwhile, as shown in FIGS. 19 to 21, the method of manufacturing the touch panel 500 according to the preferred embodiment may omit the etching process using the peelable mask 140 and directly pattern the transparent electrode 130 with a laser 155.

First, as shown in FIG. 19, after the discoloring layer 120 are formed on one surface of the transparent substrate 110 and the transparent electrode 130 is formed on the other surface of the transparent substrate 110, as shown in FIGS. 20 and 21, the discoloring layer 120 may be discolored by the laser 155 while patterning the transparent electrode 130 by irradiating the laser 155 thereto. That is, only the portion 125 corresponding to the opening 135 in the discoloring layer 120 is selectively discolored into the same color as the transparent electrode 130 by using the UV laser 155 while patterning the transparent electrode 130 to form the opening 135 by using the UV laser 155. Although the transparent electrode 130 and the discoloring layer 120 are formed on an opposite surface to each other based on the transparent substrate 110, the UV laser 155 may penetrate through the transparent substrate 110, thereby making it possible to discolor the discoloring layer 120 while patterning the transparent electrode 130 by UV laser 155.

In the touch panel 500 according to the present embodiment, the transparent electrode 130 has a single layer structure, such that it may be used as a self capacitive type touch panel or a mutual capacitive type touch panel. Further, various types of touch panels including the structure may be manufactured as described below.

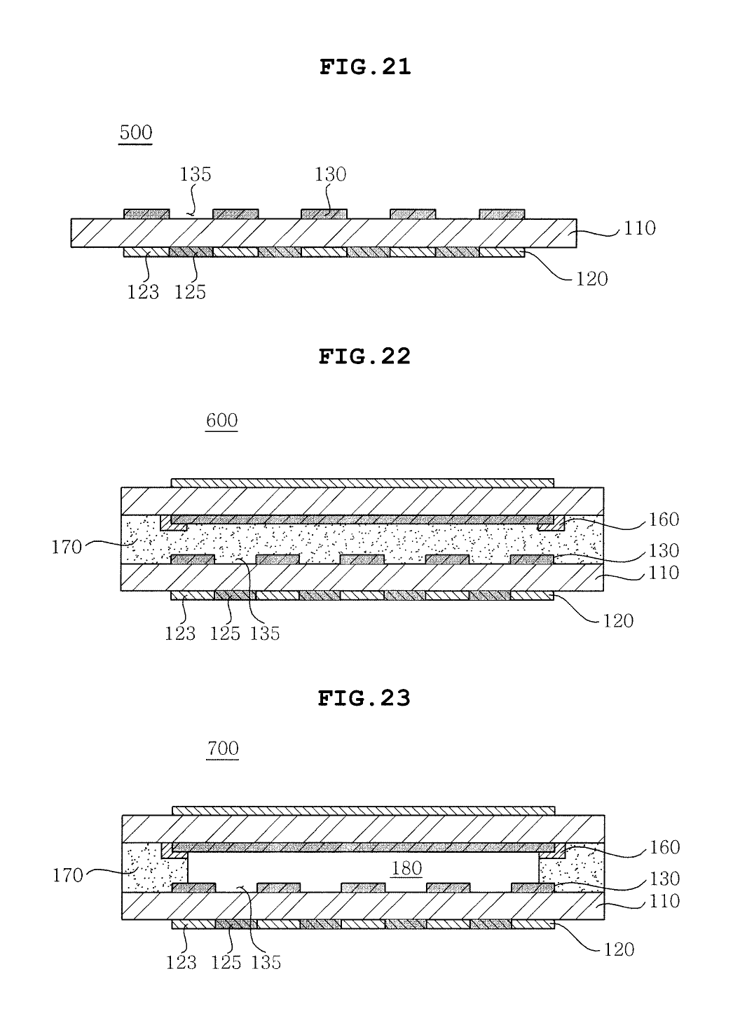

FIGS. 22 to 23 are cross-sectional views of a touch panel manufactured using the second preferred embodiment of the present invention.

Further, as shown in FIGS. 22 and 23, the mutual capacitive touch panel 600 (see FIG. 22) or the multi resistive type touch panel 700 (see FIG. 23) may be manufactured by preparing two transparent substrates 110 having the transparent electrode 130 formed on one surface thereof and bonding the two transparent substrates 110 using an adhesive layer 170 so that the transparent electrodes 130 are vertically opposite to each other. Herein, in the case of the mutual capacitive touch panel 600 (see FIG. 22), the adhesive layer 170 is bonded to the entire surface of the transparent substrate 110 so that the two transparent electrodes 130 opposite to each other are insulated. On the other hand, in the case of the multi resistive type touch panel 700 (see FIG. 23), the adhesive layer 170 is attached to only the edge of the transparent substrate 110 and thus, when the pressure of the user is applied to the adhesive layer 170, two transparent electrodes 130 may contact each other through an air-gap 180. Meanwhile, an electrode wiring 160 receiving electrical signals from the transparent electrode 130 is printed at both ends of the transparent electrode 130.

As set forth above, the present invention can prevent the recognition of the patterned transparent electrodes by a user by adopting the discoloring layer discolored into colors corresponding to the transparent electrodes, thereby making it possible to improve the visibility of the touch panel.

Further, the present invention uses the peelable mask used in the etching process even in the case where the discoloring layers are discolored by irradiating laser or light thereto when the transparent electrodes are patterned by the etching process, thereby making it possible to accurately discolor only the portions corresponding to the openings of the transparent electrodes in the discoloring layer.

In addition, the present invention discolors the discolored layers while patterning the transparent electrode with laser when the transparent electrodes are patterned by irradiating laser thereto, such that the separate discoloring process does not need to be performed during the manufacturing process of the touch panel.

Although the preferred embodiments of the present invention have been disclosed for illustrative purposes, they are for specifically explaining the present invention and thus a touch panel and a method of manufacturing the same are not limited thereto, but those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A touch panel, comprising:
a transparent substrate;
a discoloring layer formed on one surface of the transparent substrate; and
a transparent electrode formed on the discoloring layer,
wherein the transparent electrode is patterned to have an opening and the discoloring layer selectively discolors only the portion corresponding to the opening into color corresponding to the transparent electrode.

2. The touch panel as set forth in claim 1, wherein the discoloring layer is made of a polymeric material containing latent acid and color former.

3. The touch panel as set forth in claim 1, wherein the transparent electrode is made of a conductive polymer including poly-3,4-ethylenedioxythiophene/polystyrenesulfonate (PEDOT/PSS), polyaniline, polyacetylene, or polyphenylenevinylene.

4. A touch panel, comprising:
a transparent substrate:
a transparent electrode formed on one surface of the transparent substrate; and
a discoloring layer formed on the other surface of the transparent substrate,
wherein the transparent electrode is patterned to have an opening and the discoloring layer selectively discolors only the portion corresponding to the opening into color corresponding to the transparent electrode.

5. The touch panel as set forth in claim 4, wherein the discoloring layer is made of a polymeric material containing latent acid and color former.

6. The touch panel as set forth in claim 4, wherein the transparent electrode is made of a conductive polymer including poly-3,4-ethylenedioxythiophene/polystyrenesulfonate (PEDOT/PSS), polyaniline, polyacetylene, or polyphenylenevinylene.

7. A method of manufacturing a touch panel, comprising:
(A) sequentially forming a discoloring layer and a transparent electrode on one surface of a transparent substrate; and
(B) patterning the transparent electrode to form the opening and selectively discoloring only a portion corresponding to the opening in the discoloring layer into color corresponding to the transparent electrode.

8. The method of manufacturing a touch panel as set forth in claim 7, wherein step (B) includes:
(B1) arranging a patterned peelable mask on the transparent electrode;
(B2) patterning the transparent electrode to form the opening by selectively removing the exposed transparent electrode from the patterned peelable mask by an etching process; and
(B3) discoloring only the portion corresponding to the opening in the discoloring layer into color corresponding to the transparent electrode by selectively irradiating laser or light thereto.

9. The method of manufacturing a touch panel as set forth in claim 7, wherein at step (B), only the portion corresponding to the opening in the discoloring layer into color corresponding to the transparent electrode is selectively discolored by the laser, while patterning the transparent electrode to form the opening by irradiating the laser thereto.

10. The method of manufacturing a touch panel as set forth in claim 7, wherein at step (A), the transparent electrode is made of a conductive polymer including poly-3,4-ethylenedioxythiophene/polystyrenesulfonate (PEDOT/PSS), polyaniline, polyacetylene, or polyphenylenevinylene.

11. The method of manufacturing a touch panel as set forth in claim 8, wherein the laser is UV laser and the light is UV light.

12. The method of manufacturing a touch panel as set forth in claim 9, wherein the laser is UV laser.

13. The method of manufacturing a touch panel as set forth in claim 7, wherein at step (A), the discoloring layer is made of a polymeric material containing latent acid and color former.

14. A method of manufacturing a touch panel, comprising:
(A) forming a transparent electrode on one surface of a transparent substrate and forming a discoloring layer on the other surface of the transparent substrate; and
(B) patterning the transparent electrode to form an opening and selectively discoloring only a portion corresponding to the opening in the discoloring layer into color corresponding to the transparent electrode.

15. The method of manufacturing a touch panel as set forth in claim 14, wherein step (B) includes:
(B1) arranging a patterned peelable mask on the transparent electrode;
(B2) patterning the transparent electrode to form the opening by selectively removing the exposed transparent electrode from the patterned peelable mask by an etching process; and
(B3) discoloring only the portion corresponding to the opening in the discoloring layer into color corresponding to the transparent electrode by selectively irradiating laser or light thereto.

16. The method of manufacturing a touch panel as set forth in claim 14, wherein at step (B), only the portion corresponding to the opening in the discoloring layer into color corresponding to the transparent electrode is selectively discolored by the laser, while patterning the transparent electrode to form the opening by irradiating the laser thereto.

17. The method of manufacturing a touch panel as set forth in claim 14, wherein at step (A), the transparent electrode is made of a conductive polymer including poly-3,4-ethylenedioxythiophene/polystyrenesulfonate (PEDOT/PSS), polyaniline, polyacetylene, or polyphenylenevinylene.

18. The method of manufacturing a touch panel as set forth in claim 15, wherein the laser is UV laser and the light is UV light.

19. The method of manufacturing a touch panel as set forth in claim 16, wherein the laser is UV laser.

20. The method of manufacturing a touch panel as set forth in claim 14, wherein at step (A), the discoloring layer is made of a polymeric material containing latent acid and color former.
